(19) United States
(12) Patent Application Publication
(10) Pub. No.: US 2014/0177182 A1
(43) Pub. Date: Jun. 26, 2014

(54) FLEXIBLE DISPLAY AND METHOD FOR MANUFACTURING THE SAME

(71) Applicant: LG Display Co., Ltd., Seoul (KR)

(72) Inventor: Minsu CHO, Paju-si (KR)

(73) Assignee: LG Display Co., Ltd., Seoul (KR)

(21) Appl. No.: 13/961,843

(22) Filed: Aug. 7, 2013

(30) Foreign Application Priority Data
Dec. 21, 2012 (KR) 10-2012-0151148

(51) Int. Cl. H05K 7/06; H05K 3/30

(52) U.S. Cl. CPC H05K 7/06; H05K 3/30
USPC 361/749; 29/832

(57) ABSTRACT

A flexible display comprises a display panel that includes a flexible substrate and subpixels formed in a display area defined on a surface of the flexible substrate. A data driver is mounted to a data driver area defined on the surface of the flexible substrate. The flexible display can have a connector mounted to a connector area defined on the surface of the substrate. A bent portion of the flexible substrate is between the display area and the connector area and causes the connector area to be bent back towards an other surface of the flexible substrate. A system board can further be electrically connected to the connector mounted on the connector area through a cable.

### CROSS REFERENCE TO RELATED APPLICATIONS

This application claims the benefit of Korean Patent Application No. 10-2012-0151148 filed on Dec. 21, 2012, the contents of which are incorporated by reference herein in their entirety.

### BACKGROUND OF THE INVENTION

1. Field of the Invention

Embodiments of the invention relate to a flexible display and a method for manufacturing the same.

2. Discussion of the Related Art

The market of flat panel displays used as media between users and information is increasing with the development of information technology. Hence, the use of flat panel displays, such as an organic light emitting display, a liquid crystal display (LCD), an electrophoretic display, and a plasma display panel (PDP), is increasing.

The flat panel displays have been widely used in portable appliances such as, notebooks and cellular phones, as well as home appliances, such as televisions and videos, through characteristics of thin profile of the flat panel displays.

Out of the above flat panel displays, the organic light emitting display, the liquid crystal display, and the electrophoretic display may easily achieve the thin profile and also may be used as a flexible display by adding flexibility to them. Therefore, a study to add the flexibility to display devices is being continuously carried out.

When the flexible display is manufactured using the organic light emitting display, the liquid crystal display, and the electrophoretic display, a flexible substrate, for example, a polyimide film which is more flexible than plastic and glass, is used.

Although a related art flexible display uses a flexible substrate, the related art flexible display has to use a flexible printed circuit board (FPCB) for an electrical connection between a display panel and a system board. Therefore, the related art flexible display requires a process for forming an anisotropic conductive film (ACF) used to connect the display panel, the flexible printed circuit board, and the system board in a bonding area between them and a process for bonding the display panel, the flexible printed circuit board, and the system board. Further, the related art flexible display has to extend an unnecessary area because of the use of the flexible substrate and also has to continuously use, maintain, and repair a film-on glass (FOG) equipment.

### SUMMARY OF THE INVENTION

In one embodiment a flexible display comprises a display panel that includes a flexible substrate and subpixels formed in a display area defined on a surface of the flexible substrate. A data driver is mounted to a data driver area defined on the surface of the flexible substrate. The flexible display can have a connector mounted to a connector area defined on the surface of the substrate. A bent portion of the flexible substrate is between the display area and the connector area and causes the connector area to be bent back towards an other surface of the flexible substrate. A system board can further be electrically connected to the connector mounted on the connector area through a cable.

In one embodiment, a method of manufacturing a flexible display is disclosed. The method comprises forming subpixels in a display area defined on a surface of a flexible substrate; attaching a protection film on the flexible substrate; and mounting a connector to a connector area defined on the surface of the flexible substrate. The method can also comprise mounting a data driver to a data driver area defined on the surface of the flexible substrate. The flexible substrate is bent at a bendable portion of the flexible substrate between the connector area and the display area such that the connector area is bent back towards an other surface of the flexible substrate. A system board can also be electrically connected to the connector mounted on the connector area through a cable.

In one aspect, there is a flexible display including a display panel including a flexible substrate, subpixels formed in a display area defined in one surface of the flexible substrate, and a protection film protecting the subpixels, a data driver formed in a data driver area defined in the one surface of the flexible substrate, and a system board connected to the display panel, wherein the display panel and the system board have a structure, in which a flexible printed circuit board used in an electrical connection between the display panel and the system board is removed.

In another aspect, there is a method for manufacturing a flexible display including forming subpixels in a display area defined in one surface of a flexible substrate and forming pad metals in a data driver area and a connector area defined in the one surface of the flexible substrate, attaching a protection film to the one surface of the flexible substrate and forming a display panel, mounting a first connector in the connector area, chamfering the connector area to protrude the connector area from one upper side of the flexible substrate, mounting a data driver in the data driver area, and forming a system board on one surface of the display panel and connecting the first connector and a second connector formed on the system board to a cable.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic block diagram of a flexible display according to an exemplary embodiment of the invention;

FIG. 2 illustrates an example of a subpixel shown in FIG. 1;

FIGS. 3 to 12 illustrate a method for manufacturing a flexible display according to an exemplary embodiment of the invention.

### DETAILED DESCRIPTION OF THE EMBODIMENTS

Reference will now be made in detail to embodiments of the invention, examples of which are illustrated in the accompanying drawings. Wherever possible, the same reference numbers will be used throughout the drawings to refer to the same or like parts. It will be paid attention that detailed description of known arts will be omitted if it is determined that the arts can mislead the embodiments of the invention.

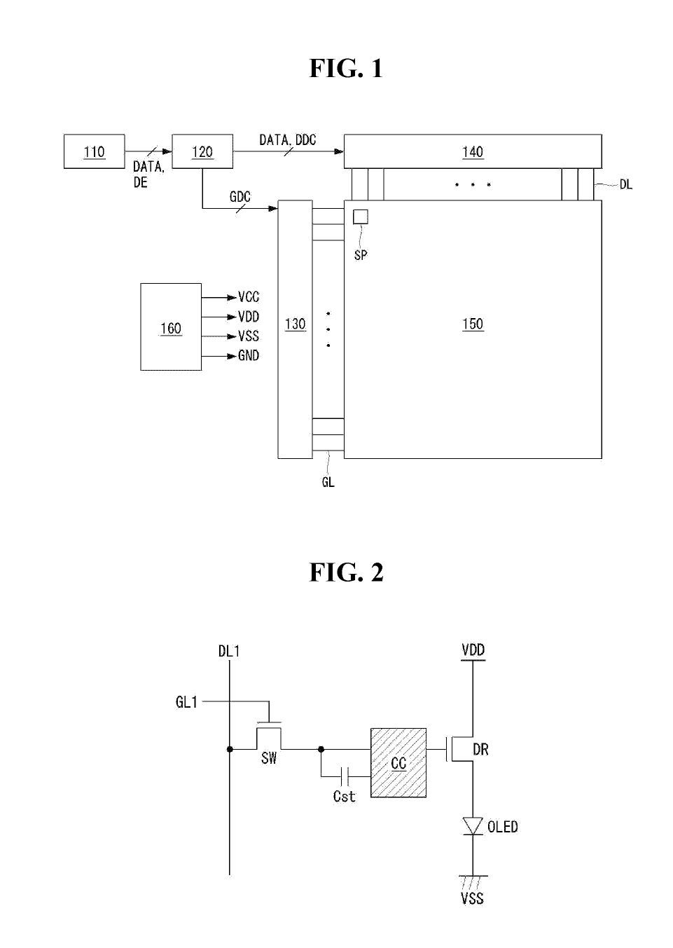

Embodiments of the invention are described below with reference to FIGS. 1 to 12.

FIG. 1 is a schematic block diagram of a flexible display according to an exemplary embodiment of the invention. FIG. 2 illustrates an example of a subpixel shown in FIG. 1.

As shown in FIG. 1, a flexible display according to an exemplary embodiment of the invention includes an image processing unit 110, a timing controller 120, a gate driver 130, a data driver 140, a display panel 150, and a power supply unit 160.

The image processing unit 110 performs image processing on an image signal DATA supplied from the outside and supplies the image signal DATA to the timing controller 120. The image processing unit 110 may supply driving signals including a data enable signal DE, a vertical sync signal Vsync, a horizontal sync signal Hsync, a clock CLK, etc. along with the image signal DATA to the timing controller 120.

The timing controller 120 collects extended display identification data (EDID) including a resolution, a frequency, timing information, etc. of the display panel 150 or compensation data from an external memory through I²C interface, etc. The timing controller 120 outputs a gate timing control signals GDC for controlling operation timing of the gate driver 130 and a data timing control signals DDC for controlling operation timing of the data driver 140. The timing controller 120 supplies the data timing control signals DDC and a digital data signal DATA to the data driver 140.

The power supply unit 160 converts electric power supplied from the outside and outputs voltages through a first high voltage line VCC, a second high voltage line VDD, a first low voltage line GND, and a second low voltage line VSS. A first high voltage, a second high voltage, a first low voltage, and a second low voltage output from the power supply unit 160 are individually supplied to the image processing unit 110, the timing controller 120, the gate driver 130, the data driver 140, and the display panel 150.

The data driver 140 samples and latches the digital data signal DATA in response to the data timing control signals DDC received from the timing controller 120 and converts the latched digital data signal DATA into analog data signals using gamma reference voltages. The data driver 140 is configured as integrated circuits (ICs). The data driver 140 may be surface mounted on the display panel 150 or may be mounted on an external substrate connected to the display panel 150. The data driver 140 supplies the analog data signals to subpixels SP included in the display panel 150 through data lines DL.

The gate driver 130 shifts a level of a gate voltage in response to the gate timing control signals GDC received from the timing controller 120 and outputs a gate signal. The gate driver 130 is configured as integrated circuits (ICs). The gate driver 130 may be mounted on the display panel 150 or may be mounted on an external substrate connected to the display panel 150. Alternatively, the gate driver 130 configured as the integrated circuits may be mounted on the display panel 150 or may be formed on the display panel 150 in the form of a gate-in panel (GIP). The gate driver 130 supplies the gate signal to the subpixels SP included in the display panel 150 through gate lines GL.

The display panel 150 displays an image corresponding to the gate signal received from the gate driver 130 and the analog data signals received from the data driver 140. The display panel 150 includes the subpixels SP, which control light to display the image. The subpixels SP included in the display panel 150 may be implemented as an organic light emitting element, a liquid crystal display element, and an electrophoresis display element. Hereinafter, the embodiment of the invention is described using the organic light emitting element as an example of the subpixels SP.

As shown in FIG. 2, the subpixel SP configured as the organic light emitting element includes a switching transistor SW, a capacitor Cst, a driving transistor DR, a compensation circuit CC, and an organic light emitting diode OLED. The switching transistor SW transmits an analog data signal supplied through a data line DL1 to the capacitor Cst in response to a gate signal supplied through a gate line GL1. The capacitor Cst stores the analog data signal as a data voltage. The driving transistor DR is driven, so that a driving current flows between the high voltage line VDD and the low voltage line VSS based on the data voltage stored in the capacitor Cst. The organic light emitting diode OLED emits light corresponding to the driving current supplied through the driving transistor DR. The compensation circuit CC compensates for a threshold voltage of the driving transistor DR. The compensation circuit CC includes at least one transistor and at least one capacitor. The compensation circuit CC may have various configurations, and a further description thereof may be briefly made or may be entirely omitted.

The subpixel configured as the organic light emitting element generally has a configuration of 2T(transistor)1C(capacitor) including a switching transistor SW, a capacitor Cst, a driving transistor DR, and an organic light emitting diode OLED. If a compensation circuit is added, the subpixel may have configurations of 3T1C, 4T2C, 5T2C, etc. The subpixel having the above-described configuration may be classified into a top emission type subpixel, a bottom emission type subpixel, and a dual emission type subpixel based on its structure.

The subpixel configured as the organic light emitting element may have a subpixel structure including a white subpixel, a red subpixel, a green subpixel, and a blue subpixel, so as to increase its light efficiency and prevent a reduction in a luminance and color sensitivity of a pure color. In this instance, the white subpixel, the red subpixel, the green subpixel, and the blue subpixel may be implemented using a white organic light emitting diode and red, green, and blue color filters or may be implemented by dividing a light emitting material included in an organic light emitting diode into white, red, green, and blue light emitting materials.

A method for manufacturing the flexible display according to the embodiment of the invention is described below.

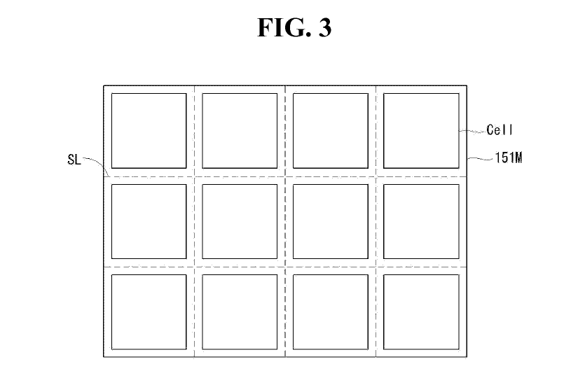

FIGS. 3 to 12 illustrate a method for manufacturing the flexible display according to the embodiment of the invention.

As shown in FIG. 3, a plurality of display cells are formed on one surface of a mother substrate 151M, and a display element is formed in each display cell. The mother substrate 151M may be formed of a material having an excellent restitution force, for example, polyethersulfone (PES), polyethylene terephthalate (PET), polyethylene naphthalate (PEN), polyimide (PI), or polycarbonates (PC). Other materials may be used. The mother substrate 151M may be configured as a flexible substrate and a glass substrate. Other substrates may be used for the mother substrate 151M.

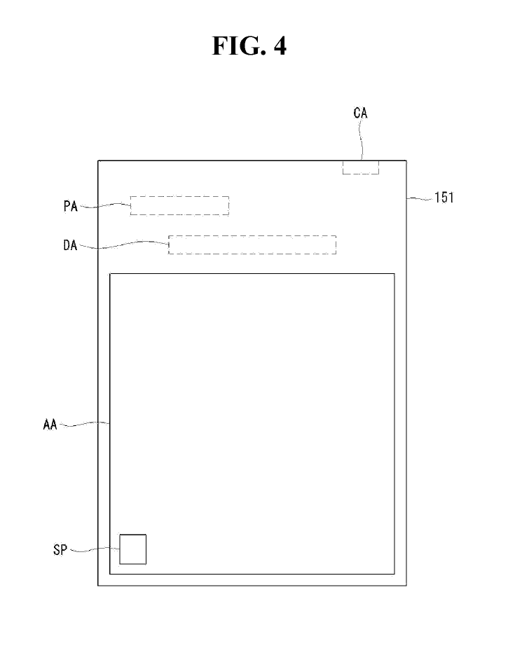

After the display element is formed in each of the display cells of the mother substrate 151M, the mother substrate 151M is cut along scribing lines SL. Hence, as shown in FIG. 4, a flexible substrate 151 corresponding to each display cell includes a display area AA in which a subpixel SP is formed, a data driver area DA on which a data driver is surface mounted, an element area PA on which a passive element (e.g., capacitor or resistor) is surface mounted, and a connector area CA on which a first connector is mounted. The embodiment of the invention uses a gate driver embedded in the flexible substrate 151 in the form of a gate-in panel (GIP), and thus a formation area of the gate driver is not separately shown.

FIG. 4 shows that the element area PA is positioned adjacent to the data driver area DA on the left side of the flexible substrate 151. However, the embodiment of the invention is not limited thereto. The element area PA may be omitted, if necessary or desired. Further, FIG. 4 shows that the connector area CA is positioned on the upper right side of the flexible substrate 151. However, the connector area CA may be positioned on the upper left side or in the upper middle of the flexible substrate 151.

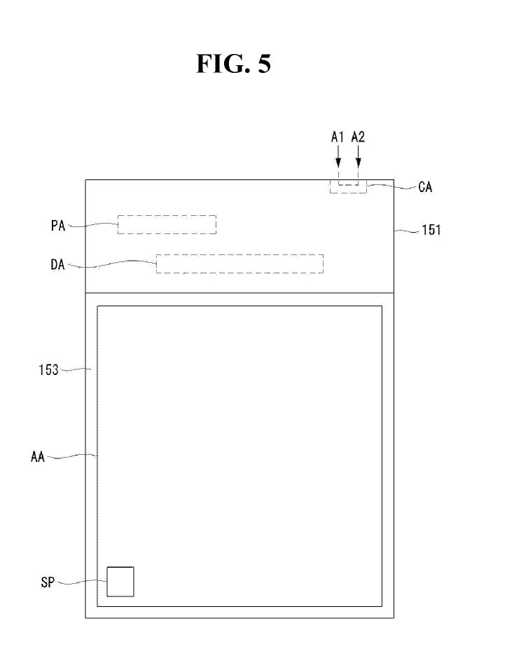

Next, as shown in FIG. 5, a protection film 153 is formed on one surface of the flexible substrate 151. The protection film 153 protects the display elements formed on the flexible substrate 151 from an external environment such as oxygen and moisture. The protection film 153 may be selected among a film type, a substrate type, and an adhesive type. Other types may be used.

The display area AA, the data driver area DA, the element area PA, and the connector area CA are formed in a process for forming the display element. The data driver area DA, the element area PA, and the connector area CA, but not the display area AA, have the similar structure.

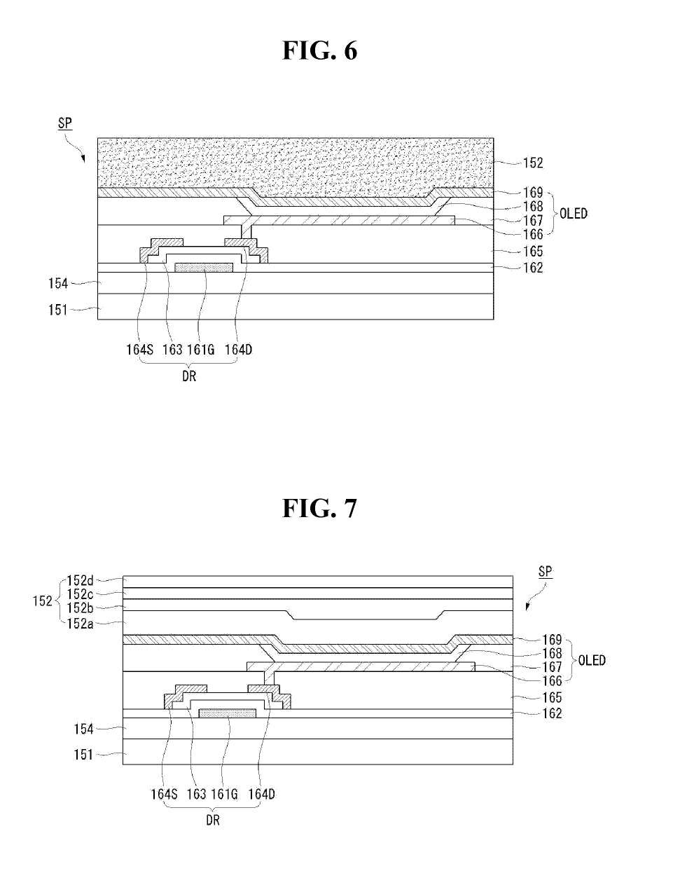

When the display element is configured as an organic light emitting element, a structure of the subpixel SP is described below with reference to FIGS. 6 and 7.

The driving transistor DR is formed on one surface of the flexible substrate 151. The driving transistor DR includes a gate electrode 161G, a semiconductor layer 163, a source electrode 164S, and a drain electrode 164D. The gate electrode 161G is formed on a buffer layer 154. A first insulating layer 162 is formed on the gate electrode 161G. The semiconductor layer 163 is formed on the first insulating layer 162. The source electrode 164S and the drain electrode 164D are formed to respectively contact both sides of the semiconductor layer 163. A second insulating layer 165 is formed on the source electrode 164S and the drain electrode 164D. In addition to the driving transistor DR, a switching transistor (not shown), a capacitor (not shown), various lines, etc. are formed on the one surface of the flexible substrate 151.

The organic light emitting diode OLED includes a lower electrode 166, an organic light emitting layer 168, and an upper electrode 169. The lower electrode 166 is formed on the second insulating layer 165. The lower electrode 166 is connected to the drain electrode 164D of the driving transistor DR exposed through the second insulating layer 165. The lower electrode 166 is formed in each subpixel. The lower electrode 166 is selected as an anode electrode or a cathode electrode. A bank layer 167 is formed on the lower electrode 166. The bank layer 167 is a layer defining an opening of the subpixel. The organic light emitting layer 168 is formed on the lower electrode 166.

The organic light emitting layer 168 includes a hole injection layer HIL, a hole transport layer HTL, a light emitting layer EML, an electron transport layer ETL, and an electron injection layer EIL. At least one of the other functional layers HIL, HTL, ETL, and EIL except the light emitting layer EML of the organic light emitting layer 168 may be omitted. The organic light emitting layer 168 may further include a blocking layer or a barrier layer for adjusting energy levels of holes and electrons. The upper electrode 169 is formed on the organic light emitting layer 168. The upper electrode 169 is a common electrode commonly connected to all of the subpixels. The upper electrode 169 is selected as a cathode electrode or an anode electrode.

A protection film 152 is formed on the upper electrode 169. As shown in FIG. 6, the protection film 152 may have a single-layered structure. In this instance, the protection film 152 may be formed of a transparent face sealant or a transparent film. Alternatively, as shown in FIG. 7, the protection film 152 may have a multi-layered structure. In this instance, the protection film 152 may be formed of an organic-inorganic complex layer including an organic layer 152a, an inorganic layer 152b, an organic layer 152c, and an inorganic layer 152d. Although not shown, the organic-inorganic complex layer may further include an absorption layer for absorbing moisture or oxygen.

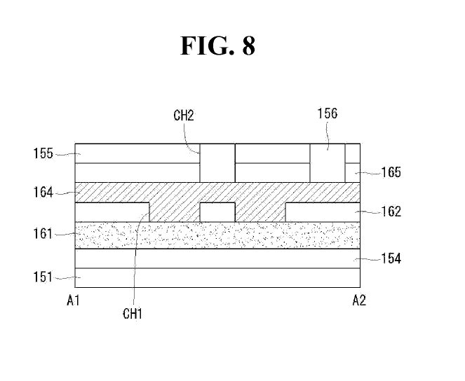

The connector area CA, in which pad metals 156 are formed, is described below with reference to FIG. 8. Since the element area PA and the data driver area DA have the structure similar to the connector area CA, a further description thereof may be briefly made or may be entirely omitted.

As shown in FIG. 8, a gate metal 161 is formed on the buffer layer 154. The first insulating layer 162 is formed on the gate metal 161. The first insulating layer 162 has a first contact hole CH1. A source-drain metal 164 is formed on the first insulating layer 162. The source-drain metal 164 is electrically connected to a gate metal 164 through the first contact hole CH1. The second insulating layer 165 is formed on the source-drain metal 164. A third insulating layer 155 is formed on the second insulating layer 165. The second insulating layer 165 and the third insulating layer 155 each have a second contact hole CH2. The pad metals 156 are formed inside the second contact hole CH2.

As shown in FIG. 8, the pad metals 156 are exposed through the third insulating layer 155. The pad metals 156 may further include tin (Sn), so that an adhesive strength between the data driver and lead (Pb) is improved when the data driver is mounted using surface mounted technology (SMT). The third insulating layer 155 is a protection layer for protecting the surfaces of the pad metals 156. The third insulating layer 155 may be formed of polyimide (PI) or a photosensitive solder resist. Other materials may be used for the third insulating layer 155. The third insulating layer 155 may be omitted, if necessary or desired.

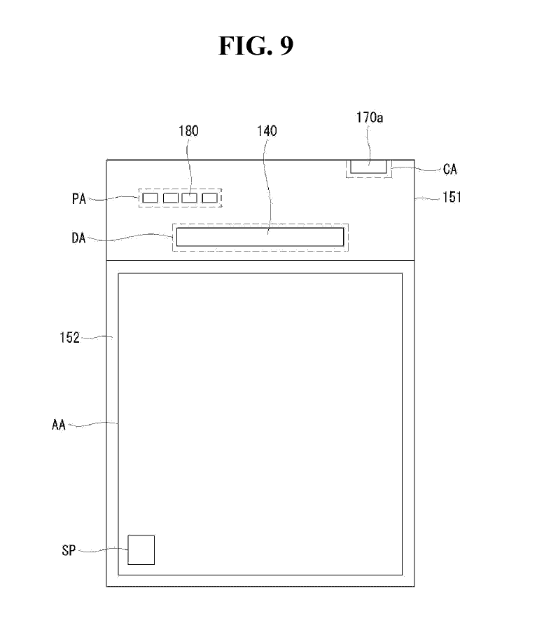

Next, as shown in FIG. 9, a passive element 180 (for example, a bypass capacitor) and a first connector 170a are mounted in the element area PA and the connector area CA using the surface mounted technology.

Next, as shown in FIG. 9, the data driver 140 is mounted in the data driver area DA though a chip-on glass (COG) process. In the COG process, the data driver 140 is mounted on pad bumps formed in the data driver area DA using an anisotropic conductive film (ACF).

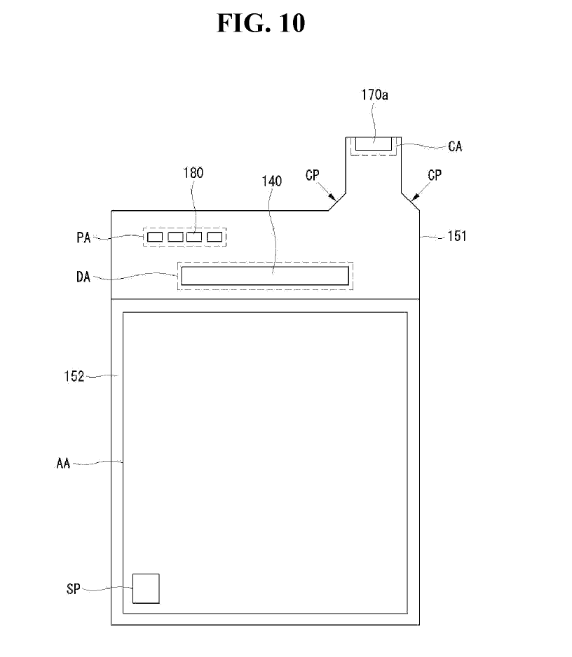

Next, as shown in FIG. 10, a portion of one side of the flexible substrate 151 is scribed to remove a useless portion of the flexible substrate 151, so that the connector area CA protrudes further than the other area, for example, the element area PA and the data driver area DA. When a portion of one side of the flexible substrate 151 is scribed, a chamfering process indicated by “CP” in FIG. 10 may be performed so as to obtain various shapes of the flexible substrate 151. However, the embodiment of the invention is not limited thereto.

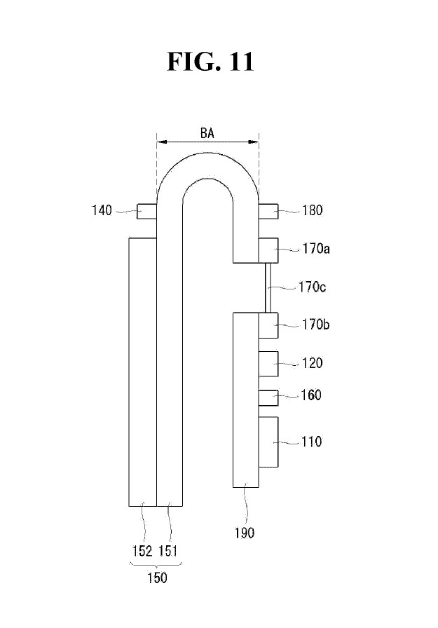

Next, as shown in FIG. 11, the flexible substrate 151 is bent in a bendable area BA that is between the connector area CA and the display area. The connector area CA is bent back in a direction of the other surface (or the back surface) of the flexible substrate 151 that is opposite from the top surface. A system board 190, on which the image processing unit 110, the timing controller 120, and the power supply unit 160 are mounted, is positioned on the other surface of the flexible substrate 151. A second connector 170b mounted on the system board 190 is connected to a first connector 170a mounted on the flexible substrate 151 through a cable 170c, which electrically connects the system board 190 to the first connector 170a of the flexible substrate 151. FIG. 11 shows that the bendable area BA is between the data driver 140 and the passive element 180. When the passive element 180 is omitted, the bendable area BA is defined as a bending portion between the data driver 140 and the first connector 170a.

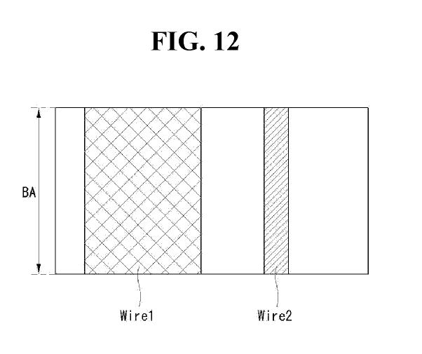

As shown in FIG. 12, when the connector area CA is bent in the direction of the other surface of the flexible substrate 151, a first line Wire1, which has a width greater than a second line Wire2, among the lines Wire1 and Wire2 formed in the bending area BA may have a mesh shape. The first line Wire1 wider than the second line Wire2 may be power supply lines such as the first high voltage line VCC, the second high voltage line VDD, the first low voltage line GND, and the second low voltage line VSS. On the other hand, the second line Wire2 may be signal lines such as the data lines.

Because the flexible substrate 151 has the flexibility but is weak in rigidity, a reinforced substrate may be additionally formed on the other surface of the flexible substrate 151. The reinforced substrate may be attached to the flexible substrate 151 using a double-sided tape or an adhesive, etc. The reinforced substrate may be formed of a metal material such as aluminum (Al) and stainless (SUS304). Other materials may be used.

As described above, the embodiment of the invention uses the flexible printed circuit board in a portion of the flexible substrate and electrically connects the display panel to the system board through the connector, thereby simplifying the configuration and the process of the flexible display. Furthermore, the embodiment of the invention omits the flexible printed circuit board and thus does not need to extend an unnecessary area and continuously use, maintain, and repair a film-on glass (FOG) equipment. Hence, the manufacturing cost of the flexible display is reduced.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A flexible display comprising:
a display panel including a flexible substrate and subpixels formed in a display area defined on a surface of the flexible substrate; and
a data driver mounted to a data driver area defined on the surface of the flexible substrate.

2. The flexible display of claim 1, the display panel further comprising a passive element mounted to an element area defined on the surface of the flexible substrate.

3. The flexible display of claim 1, further comprising:
a connector mounted to a connector area defined on the surface of the flexible substrate,
wherein the flexible substrate includes a bent portion between the display area and the connector area, the bent portion causing the connector area to be bent back towards an other surface of the flexible substrate.

4. The flexible display of claim 3, further comprising:
a system board electrically connected to the connector mounted to the connector area.

5. The flexible display of claim 4, further comprising:
a cable electrically connecting the system board to the connector mounted to the connector area.

6. The flexible display of claim 3, wherein the connector area protrudes from a side of the flexible substrate.

7. The flexible display of claim 3, wherein at least one conductive line formed on the bent portion of the flexible substrate has a mesh shape.

8. The flexible display of claim 3, wherein the data driver is mounted to the data driver area defined on the surface of the flexible substrate using surface mounted technology (SMT) and the connector is mounted to the connector area defined on the surface of the flexible substrate using SMT.

9. The flexible display of claim 1, wherein the data driver area includes:
a gate metal formed on the flexible substrate;
a first insulating layer formed on the gate metal;
a source-drain metal formed on the first insulating layer;
a second insulating layer formed on the source-drain metal; and
pad metals formed on the second insulating layer and connected to the source-drain metal,
wherein the data driver is mounted to the pad metals.

10. The flexible display of claim 9, wherein the gate metal and the source-drain metal are electrically connected through at least one first contact hole formed in the first insulating layer, and
wherein the source-drain metal and the pad metals are electrically connected through at least one second contact hole formed in the second insulating layer.

11. A method for manufacturing a flexible display comprising:
forming subpixels in a display area defined on a surface of a flexible substrate;
attaching a protection film on the flexible substrate; and
mounting a connector to a connector area defined on the surface of the flexible substrate.

12. The method of claim 11, further comprising:
removing a useless area except for a data driver, element and connector area by a chamfering process.

13. The method of claim 11, further comprising:
mounting a passive element to an element area defined on the surface of the flexible substrate.

14. The method of claim 11, further comprising:
electrically connecting a system board to the connector mounted to the connector area.

15. The method of claim 11, wherein the system board is electrically connected to the connector mounted to the connector area with a cable.

16. The method of claim 11, further comprising:
mounting a data driver to a data driver area defined on the surface of the flexible substrate; and
bending the flexible substrate at a bendable portion of the flexible substrate between the display area and the connector area such that the connector area is bent back towards an other surface of the flexible substrate.

17. The method of claim 16, further comprising:
forming at least one mesh shaped conductive line on the bendable portion of the flexible substrate.

18. The method of claim 16, wherein the data driver is mounted to the data driver area defined on the surface of the flexible substrate using surface mounted technology (SMT) and the connector is mounted to the connector area defined on the surface of the flexible substrate using SMT.

19. The method of claim 16, further comprising:
forming the data driver area by:
forming a gate metal on the flexible substrate;
forming a first insulating layer on the gate metal;
forming a source-drain metal on the first insulating layer;
forming a second insulating layer formed on the source-drain metal; and
forming pad metals on the second insulating layer that are connected to the source-drain metal,
wherein the data driver is mounted to the pad metals.

20. The method of claim 19, wherein the gate metal and the source-drain metal are electrically connected through at least one first contact hole formed in the first insulating layer,
wherein the source-drain metal and the pad metals are electrically connected through at least one second contact hole formed in the second insulating layer.
